(19) United States
(12) Patent Application Publication
(10) Pub. No.: US 2008/0284435 A1
(43) Pub. Date: Nov. 20, 2008

(54) Magnetic Resonance Coil Element With Embedded Electronics Module

(75) Inventors: Johannes Overweg, Uelzen (DE); Peter Mazurkewitz, Hamburg (DE); Christoph G. Leussler, Hamburg (DE)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS NV, Eindhoven (NL)

(21) Appl. No.: 10/595,956

(22) PCT Filed: Nov. 16, 2004
(86) PCT No.: PCT/IB2004/052452

§ 371 Date: May 22, 2006

Related U.S. Application Data
(60) Provisional application No. 60/524,954, filed on Nov. 25, 2003.

(51) Int. Cl. G01R 33/341

(52) U.S. Cl. 324/318

(57) ABSTRACT

A magnetic resonance imaging system includes main magnet (20) that produces a substantially spatially and temporally constant main magnetic field within a field of view. Magnetic field gradient coils (30) impose selected magnetic field gradients on the main magnetic field within the field of view. At least one radio frequency coil (44, 44′, 44″, 144, 154) is arranged to detect a magnetic resonance signal induced by an applied radio frequency pulse. The at least one radio frequency coil includes a radio frequency antenna (90) and electronics module (78, 78′) disposed on a substrate (72). The electronics are electrically connected with the radio frequency antenna (90). The electronics are mounted in a centered region (96) surrounded by the radio frequency antenna.

The following relates to the magnetic resonance arts. It finds particular application in surface coils and surface coil arrays used in magnetic resonance imaging, and will be described with particular reference thereto. However, it also finds application in other types of radio frequency coils used for transmitting radio frequency excitation pulses and for receiving magnetic resonance signals.

Surface receive coils are used in magnetic resonance imaging to obtain good radio frequency coupling with a region of interest. For larger regions of interest, more than one surface coil can be used to provide greater coverage. Moreover, in applications such as sensitivity encoding (SENSE), the coils are used in parallel to image a common region of interest at an increased data acquisition rate.

A problem arises in that radio frequency current induced in one surface coil can couple to neighboring surface coils, producing artifacts or other degradation of the resulting reconstructed image. To address this problem, a pre-amplifier with matching circuitry is commonly used to provide a high output impedance as seen by the coil. Moreover, radio frequency baluns, traps, or the like can be incorporated to further suppress induced currents. Detuning circuitry is generally provided for each coil to detune the coil from the magnetic resonance frequency during the transmit phase of magnetic resonance imaging. Additional monitoring circuitry, safety interlock circuitry, or the like is also optionally coupled to each surface coil. The overall electronics package including, for example, the pre-amplifier and matching circuitry, radio frequency trap, detuning circuitry, monitoring and safety circuitry is commonly arranged in an electronic module.

For optimal operation, the electronic module should be close to the surface coil. However, the electronic module can adversely affect the imaging. For example, some electronic components may produce substantial radio frequency noise or interference. Moreover, ground planes, radio frequency shields, and the like can produce magnetic field flux expulsion effects that can distort the magnetic field in the vicinity of the electronic module and change the coil sensitivity to the magnetic resonance signal. Because of these and other concerns, the electronic module is generally positioned displaced outside a periphery of the surface coil.

While such displaced positioning of the electronic module improves image quality, it complicates design of surface coil arrays. Lead lines between the coils and their associated electronics provide additional opportunity for coupling and cross-talk. Large surface coil arrays provide large volume coverage. For parallel imaging techniques such as SENSE, a large array of coils can enable higher SENSE factors or otherwise increased data acquisition rates. Large arrays, for example rectangular arrays of N×M coils where N>2 and M>2, have interior coils that are completely surrounded by other surface coils. In such arrays, the interior coils are not readily connected with electronics arranged at the coil periphery.

The present invention contemplates an improved apparatus and method that overcomes the aforementioned limitations and others.

According to one aspect, a radio frequency coil is disclosed. A radio frequency antenna is disposed on a substrate. An electronics module is disposed on the substrate and is electrically connected with the radio frequency antenna.

According to another aspect, a radio frequency coils array is disclosed. A plurality of radio frequency coils are arranged such that the radio frequency antennae of the plurality of radio frequency coils span a coils array surface. Each radio frequency coil includes a substrate, a radio frequency antenna disposed on the substrate, and an electronics module disposed on a central region of the substrate and electrically connected with the radio frequency antenna. The radio frequency antenna includes a conductor disposed on the substrate outside of and at least partially surrounding the central region of the substrate.

According to yet another aspect, a magnetic resonance imaging system is disclosed. A main magnet produces a substantially spatially and temporally constant main magnetic field within a field of view. Magnetic field gradient coils impose selected magnetic field gradients on the main magnetic field within the field of view. A means is provided for applying a radio frequency pulse to the field of view. At least one radio frequency coil is arranged to detect a magnetic resonance signal induced by the applied radio frequency pulse. The at least one radio frequency coil includes a radio frequency antenna disposed on a substrate and an electronics module disposed on the substrate. The electronics module is electrically connected with the radio frequency antenna.

According to still yet another aspect, a magnetic resonance imaging method is provided. Magnetic resonance is excited in an imaging subject. A magnetic resonance signal is received using one or more radio frequency coils each including a radio frequency antenna disposed on a substrate and an electronics module disposed on the substrate and electrically connected with the radio frequency antenna. The radio frequency antenna of each coil is in proximity to the imaging subject.

One advantage resides in improved compactness of a surface coil for magnetic resonance imaging.

Another advantage resides in reduced external electrical wiring in a surface coil array.

Yet another advantage resides in more adaptable and configurable three-dimensional surface coils array construction.

Numerous additional advantages and benefits will become apparent to those of ordinary skill in the art upon reading the following detailed description of the preferred embodiments.

The invention may take form in various components and arrangements of components, and in various process operations and arrangements of process operations. The drawings are only for the purpose of illustrating preferred embodiments and are not to be construed as limiting the invention.

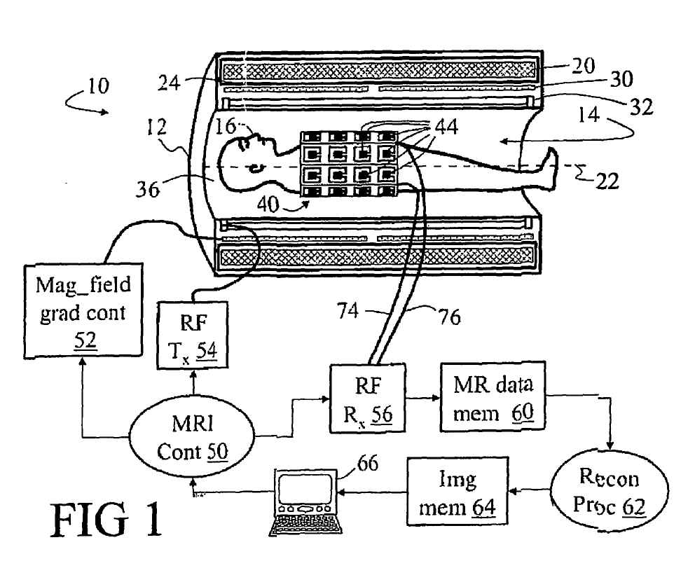

FIG. 1 diagrammatically shows a magnetic resonance imaging system employing a generally cylindrical radio frequency surface coils array.

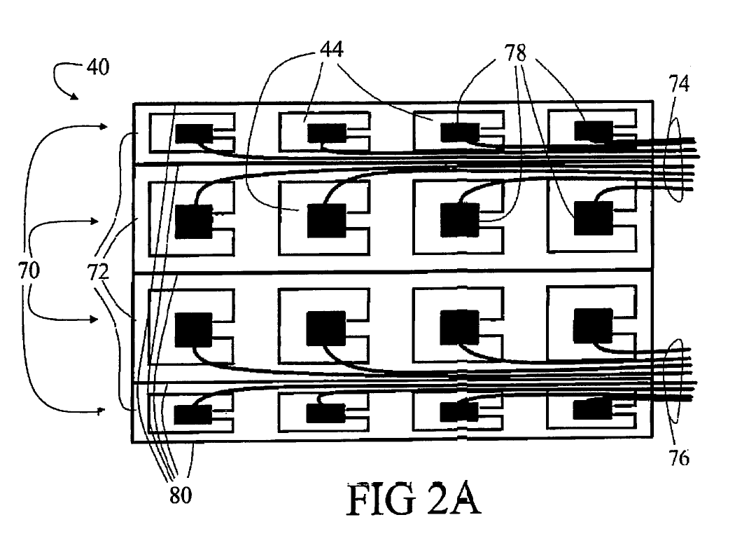

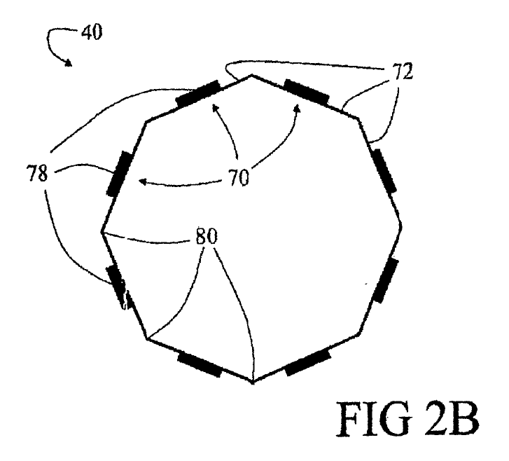

FIGS. 2A and 2B shows a side view and an end view, respectively, of the generally cylindrical radio frequency surface coils array of FIG. 1. In FIG. 2B, the cable bundles are not shown.

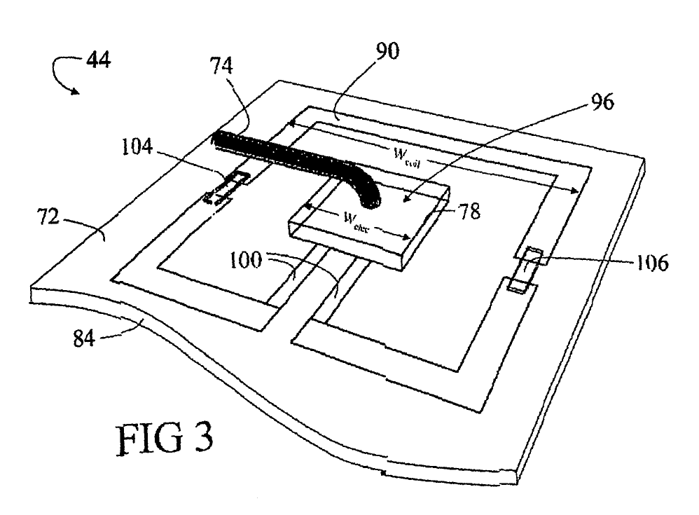

FIG. 3 diagrammatically shows one embodiment of the radio frequency surface coils of FIGS. 1, 2A, and 2B.

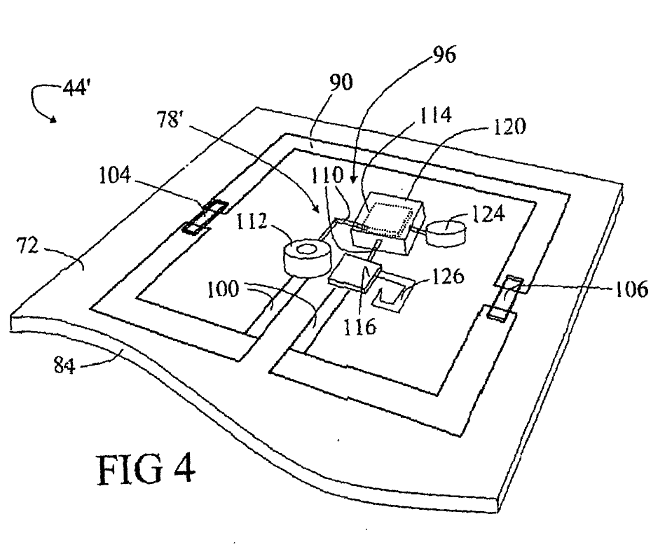

FIG. 4 diagrammatically shows another embodiment of the radio frequency surface coils of FIGS. 1, 2A, and 2B, in which the electronic module is fabricated on the coil substrate.

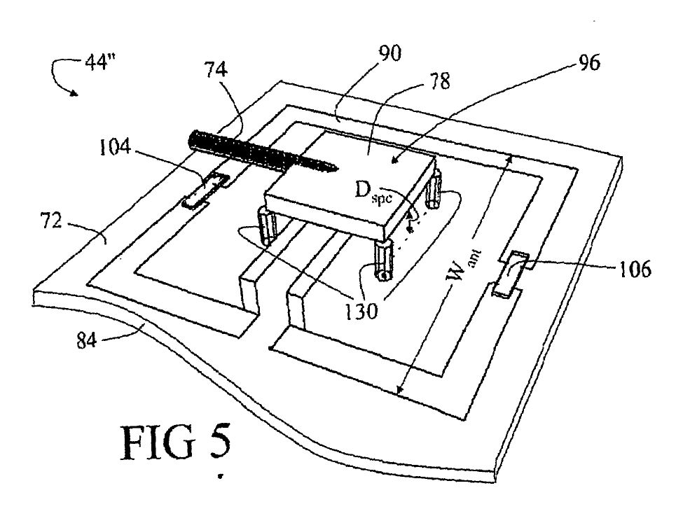

FIG. 5 diagrammatically shows yet another embodiment of the radio frequency surface coils of FIGS. 1, 2A, and 2B, in which the electronic module is separated from the substrate by spacers or standoffs.

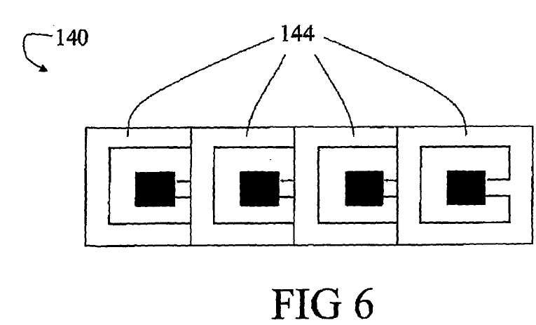

FIG. 6 diagrammatically shows a linear coils array in which the coils partially overlap.

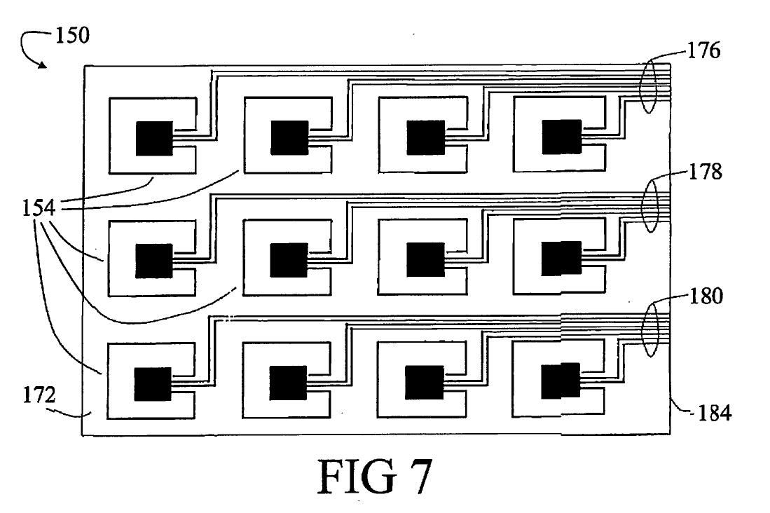

FIG. 7 diagrammatically shows a 3×4 rectangular coils array in which the coils share a common substrate that includes printed circuit buses providing electrical access to the coils from an edge of the coils array.

With reference to FIG. 1, a magnetic resonance imaging scanner 10 includes a housing 12 defining a generally cylindrical scanner bore 14 inside of which an associated imaging subject 16 is disposed. Main magnetic field coils 20 are disposed inside the housing 12, and produce a main B₀ magnetic field directed generally along and parallel to a central axis 22 of the scanner bore 14. The main magnetic field coils 20 are typically superconducting coils disposed inside cryoshrouding 24, although resistive main magnets can also be used. The housing 12 also houses or supports magnetic field gradient coils 30 for selectively producing magnetic field gradients in the bore 14. The housing 12 further houses or supports a radio frequency body coil 32 for selectively exciting and/or detecting magnetic resonances. The housing 12 typically includes a cosmetic inner liner 36 defining the scanner bore 14.

A surface coil array 40 disposed inside the bore 14 includes a plurality of surface coils 44. The surface coil array 40 can be used as a phased array of receivers for parallel imaging, as a sensitivity encoding (SENSE) coil for SENSE imaging, or the like. In another approach, the coils 44 image different areas of the imaging subject 16. The main magnetic field coils 20 produce a main B₀ magnetic field. A magnetic resonance imaging controller 50 operates magnetic field gradient controllers 52 to selectively energize the magnetic field gradient coils 30, and operates a radio frequency transmitter 54 coupled to the radio frequency coil 32 or the surface coil array 40 to selectively inject radio frequency excitation pulses into the subject 16.

By selectively operating the magnetic field gradient coils 30 and the radio frequency coil 32 magnetic resonance is generated and spatially encoded in at least a portion of a region of interest of the imaging subject 16. By applying selected magnetic field gradients via the gradient coils 30, a selected k-space trajectory is traversed, such as a Cartesian trajectory, a plurality of radial trajectories, or a spiral trajectory. Alternatively, imaging data can be acquired as projections along selected magnetic field gradient directions. During imaging data acquisition, the magnetic resonance imaging controller 50 operates a radio frequency receiver 56 coupled to the coils array 40 to acquire magnetic resonance samples that are stored in a magnetic resonance data memory 60.

The imaging data are reconstructed by a reconstruction processor 62 into an image representation. In the case of k-space sampling data, a Fourier transform-based reconstruction algorithm can be employed. Other reconstruction algorithms, such as a filtered backprojection-based reconstruction, can also be used depending upon the format of the acquired magnetic resonance imaging data. For SENSE imaging data, the reconstruction processor 62 reconstructs folded images from the imaging data acquired by each coil, and then combines the folded images along with coil sensitivity parameters to produce an unfolded reconstructed image.

The reconstructed image generated by the reconstruction processor 62 is stored in an image memory 64, and can be displayed on a user interface 66, stored in non-volatile memory, transmitted over a local intranet or the Internet, viewed, stored, manipulated, or so forth. The user interface 66 can also enable a radiologist, technician, or other operator of the magnetic resonance imaging scanner 10 to communicate with the magnetic resonance imaging controller 50 to select, modify, and execute magnetic resonance imaging sequences.

With continuing reference to FIG. 1 and with further reference to FIGS. 2A and 2B, the surface coil array 40 includes a plurality of linear coil arrays 70 each having four, in the illustrated embodiment, surface coils 44 fabricated on a common substrate 72. In the illustrated surface coil array 40 there are eight linear coil arrays 70, only four of which are visible in the side views of FIGS. 1 and 2A. Electrical cable bundles 74, 76 (shown diagrammatically in FIG. 1 and in more detail in FIG. 2A; omitted from FIG. 2B) connect to electronic modules 78 that are disposed on top of each surface coil 44 to provide electrical power, to transmit a signal corresponding to the radio frequency signal received by the coil 44, and to provide other optional input to and output from the coil 44. Two additional cable bundles (not shown) substantially similar the cable bundles 74, 76 connect to the four linear coil arrays that are not visible in the side views of FIGS. 1 and 2A. In the embodiment illustrated in FIGS. 1, 2A, and 2B, each linear coil array 70 is substantially planar, and hinged connections 80 connect long edges of the linear coil arrays 70 to define the generally cylindrical coil array 40 which has a hexagonal cross-section as best seen in FIG. 2B.

With reference to FIG. 3, one of the radio frequency surface coils 44 is shown in greater detail. FIG. 3 shows an end coil of one of the linear coil arrays 70; a broken end 84 diagrammatically indicates continuation of the common substrate 72 to the other surface coils of the linear coils array 70. The common substrate 72 is generally planar, which plane is flexed into an arc in some embodiments. An electrically conductive film of copper or another electrically conductive material defines a generally planar electrically conductive loop 90 or other conductor shape disposed on the substrate 72 that functions as a radio frequency antenna for receiving a magnetic resonance signal. In one suitable fabrication approach, a copper-coated substrate of plastic or another insulating material is lithographically processed to remove the copper coating from areas of the substrate such that the remaining copper-coated areas define the antenna loop 90 on the substrate 72. Such lithography is readily applied to the copper coated common substrate to define the four coils of the linear coils array 70.

The electronics module 78 is disposed on the substrate 72 in a central region 96 of the substrate 72, with the radio frequency antenna loop 90 outside of and at least partially surrounding the central region 96. Ends 100 of the antenna loop 90 extend into the central region 96 to electrically connect the antenna 90 with the electronic module 78. In one embodiment, the electronic module 78 has a width or other lateral dimension (W_{elec}) that is less than or about three-fifths of a width or other lateral dimension (W_{coil}) of the radio frequency antenna 90. The electronics module contains various electronic components for operating the surface coil 44, such as a pre-amplifier with matching circuitry, electronic resonance detuning circuitry, monitoring circuitry, safety interlocks circuitry, radio frequency traps or baluns, electric power distribution circuitry, or the like.

The electronics module 78 is separately housed and optionally contains a ground plane and/or a radio frequency shield that produce substantial magnetic flux expulsion. Even if the electronics module 78 does not contain either a radio frequency shield or a ground plane, various radio frequency electronic components contained in the module 78 typically produce some magnetic flux expulsion effects. However, because the antenna loop 90 measures the total radio frequency flux enclosed by the loop 90, magnetic field distortions in the central region 96 have a limited effect on the magnetic resonance signal received by the antenna loop 90. As an example, if the lateral dimension (W_{elec}) of the electronics module 78 is about one-half of the lateral dimension (W_{coil}) of the antenna 90, the loop sensitivity to the magnetic resonance signal is reduced by less than 10%. In order to minimize the effect of flux expulsion, the electronics module 78 should be located close to the center of the central region 96 surrounded by the antenna 90. The electronics module 78 should be located close to the center of the antenna loop 90.

In one embodiment, the antenna loop 90 is interrupted by one or more in-line capacitors 104, 106 or other reactive elements, which provide resonance frequency tuning, d.c. current blocking, or other effects. While the single-turn, substantially square antenna loop 90 is illustrated, it will be appreciated that the surface coil can include a multiple-turn antenna loop, a circular or otherwise-shaped antenna loop, or the like. Furthermore, it is contemplated to use a radio frequency antenna topology other than a complete loop, such as one or more electrically conductive fingers extending partway around the central region 96.

With reference to FIG. 4, another surface coil 44′ is similar in some respects to the surface coil 44. The surface coil 44′ is also suitable for use in the coils array 40. In describing the surface coil 44′, components that are unchanged respective to the surface coil 44 are labeled using identical reference numbers, while components that are modified respective to the surface coil 44 are labeled using corresponding primed reference numbers.

In the surface coil 44′, the separately housed electronic module is replaced by an electronics module 78′ that is constructed directly on the central region 96 of the substrate 72. The electronic module 78′ includes printed circuit traces 110 that are lithographically defined during the lithographic defining of the antenna loop 90, or by another lithography process. One or more discrete electronic components, such as a toroidal inductor 112, a radio frequency signal processing component 114, and a transmitter circuit 116, are disposed on the central region 96 of the substrate 72 and are interconnected by the printed circuit traces 110. In both electronic modules 78, 78′, it is preferred to use toroidal inductors, solenoidal inductors with balanced turns, or other types of inductors which limit production of stray magnetic fields.

Optionally, one or more components that produce substantial radio frequency noise or interference, such as the radio frequency signal processing component 114, are enclosed in a radio frequency shield 120. Other components, such as the inductor 112 and the transmitter circuit 116, which are “quiet” and do not produce substantial radio frequency noise or interference, are suitably disposed outside of the radio frequency shield 120. This allows the size of the radio frequency shield 120 to be reduced to a size sufficient to house the noisy circuit components, thus reducing magnetic flux expulsion.

However, it is also contemplated to instead enclose the entire electronic module 78′ in a radio frequency shield. For example, in the surface coil 44 of FIG. 3, the separate housing of the electronic module 78 can also act as a radio frequency shield for the enclosed electronics.

With reference returning to FIG. 4, rather than attaching the surface coil 44′ to the electrical cable bundle, it receives electrical power from a battery 124 and transmits a signal corresponding to the received magnetic resonance signal by a transmit antenna 126 operated by the transmitter circuit 116. A suitable wireless transmission system for wireless transmitting the magnetic resonance signal from the coil 44′ are described in Leussler, U.S. Pat. No. 5,245,288. Of course, the wireless transmission system can be used with the other embodiments and the cable bundle can be used with the FIG. 4 embodiment.

With reference to FIG. 5, another surface coil 44″ is similar in some respects to the surface coil 44 of FIG. 3. The surface coil 44″ is also suitable for use in the coils array 40. In describing the surface coil 44″, components that are unchanged respective to the surface coil 44 are labeled using identical reference numbers. The surface coil 44″ differs from the surface coil 44 principally in that the electronics module 78 is spaced apart from the substrate 72 by spacer elements 130. The spacers 130 define a separation D_{spc} between the plane of the electronics module 78 and the plane of the radio frequency antenna 90. In one preferred embodiment, the separation D_{spc} that is about one-fifth of a lateral width Wₐₙₜ of the antenna 90, which is sufficient to provide substantial reduction in distortion of the magnetic resonance signal measured by the antenna 90. A larger separation provides greater reduction of the distortion; however, typically the size of the surface coils array 40, and hence the size of the separation D_{spc}, is constrained by the bore 14 or by other spatial limitations.

While the surface coils 44, 44′, 44″ have been described with reference to the specific coils array 40 shown in FIGS. 1, 2A, and 2B, it will be appreciated that the coils 44, 44′, 44″ can be employed singly, or can be employed in arrays with other topologies. In the coils array 40, a curved array geometry is obtained using generally planar linear coils arrays 70 by use of the hinged connections 80 that allow the planar substrates 72 of some coils 44 to be tilted with respect to the planar substrates of other coils 44. In another approach for obtaining a curved surface coil, it is contemplated to use a flexible substrate 72 so that the single coil or a coils array constructed from a plurality of coils can flexed or curved.

With reference to FIG. 6, a linear coils array 140 is constructed of a plurality of radio frequency surface coils 144, each of which can correspond, for example, to one of the surface coils 44, 44′, 44″ shown in FIGS. 3-5. The surface coils 144 do not share a common substrate; rather, each coil 144 has its own substrate. The coils 144 are partially overlapped in the coils array 140, as shown. Rather than overlapping the coils 144, the coils 144 can instead substantially abut, or the coils 144 can be spaced apart from one another in the coils array. Moreover, it will be appreciated that a two-dimensional array of coils 144 can be similarly constructed, in which each coil 144 has its own unshared substrate.

With reference to FIG. 7, a two-dimensional coils array 150 includes a 3×4 array of rectangular coils 154 that share a common substrate 172. Each of the coils 154 can correspond, for example, to one of the surface coils 44, 44′, 44″ shown in FIGS. 3-5. Printed circuit buses 176, 178, 180 are lithographically defined on the substrate 172, typically during lithographic definition of the antenna loops of the coils 154. The printed circuit buses 176, 178, 180 provide electrical access to the electronic modules of the coils 154 from an edge 184 of the coils array 150. The printed circuit buses 176, 178, 180 thus replace the electrical cable bundles 74, 76 of the coils array 40 shown in FIG. 2A. The coils array 150 can be planar or, if the substrate 172 is made of a flexible plastic or other flexible electrically insulating material, the coils array 150 may be flexible. In the latter case, the surface coils array 150 may be flexed to better conform with a curved surface of the imaging subject 16.

Although lithographically patterned films on the substrate 72 have been described, it is also contemplated to use electroplating or the like to form the electrically conductive films described herein. Moreover, while receive coils have been described, transmit coil arrays can be similarly constructed. Still further, while surface coils have been described, head coils and other coils can similarly be constructed with embedded electronics by arranging the electronics with a small magnetic field flux repulsion cross-section and by arranging the electronics near a center of a receive coil loop of the magnetic resonance receive coil.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

1. A radio frequency coil comprising:
a substrate;
a radio frequency antenna (90) disposed on the substrate; and
an electronics module disposed on the substrate and electrically connected with the radio frequency antenna.

2. The radio frequency coil as set forth in claim 1, wherein:
the electronics module is disposed on a central region of the substrate; and
the radio frequency antenna includes a conductor disposed on the substrate outside of and at least partially surrounding the central region of the substrate.

3. The radio frequency coil as set forth in claim 2, wherein the conductor of the radio frequency antenna comprises:
a conductive film disposed on the substrate defining at least one conductive loop substantially surrounding the central region of the substrate, ends of said at least one conductive loop extending into the central region of the substrate and connecting with the electronics module.

4. The radio frequency coil as set forth in claim 3, wherein the substrate comprises:
a flexible electrically insulating material.

5. The radio frequency coil as set forth in claim 3, wherein the electronic module comprises:
printed circuitry disposed on the substrate; and
one or more discrete circuit components electrically connected via the printed circuitry.

6. The radio frequency coil as set forth in claim 2, further comprising:
at least one spacer element disposed between the substrate and the electronics module, the at least one spacer element defining a spacing between the electronics module and the radio frequency antenna.

7. The radio frequency coil as set forth in claim 6, wherein the spacing is at least about one-fifth of a lateral dimension of radio frequency antenna.

8. The radio frequency coil as set forth in claim 2, wherein the electronics module has a lateral dimension that is less than or about three-fifths of a lateral dimension of the radio frequency antenna.

9. The radio frequency coil as set forth in claim 1, wherein the electronic module comprises:
a wireless transmitter transmitting a transmission signal representative of a radio frequency signal received by the radio frequency antenna.

10. The radio frequency coil as set forth in claim 1, wherein the electronic module comprises:
a one or more noisy circuit components generating substantial radio frequency interference;
one or more quiet circuit components not generating substantial radio frequency interference; and
a radio frequency shield disposed around the one or more noisy circuit components but not around the one or more quiet circuit components.

11. The radio frequency coil as set forth in claim 10, wherein:
the radio frequency antenna defines a loop surrounding a central region of the substrate; and
the radio frequency shield is disposed substantially centered in the central region of the substrate.

12. The radio frequency coil as set forth in claim 1, wherein the electronic module does not include a ground plane.

13. The radio frequency coil as set forth in claim 1, wherein inductors of the electronic module are selected from a group consisting of:
toroidal inductors, and
solenoidal inductors with balanced turns.

14. A radio frequency coils array comprising:
a plurality of radio frequency coils as set forth in claim 2 arranged such that the radio frequency antennae of the plurality of radio frequency coils span a coil array surface.

15. The radio frequency coils array as set forth in claim 14, wherein the substrates of at least some of the plurality of radio frequency coils are tilted with respect to the substrates of other coils of the plurality of radio frequency coils such that the coil array surface is non-planar.

16. The radio frequency coils array as set forth in claim 14, wherein at least one coil of the plurality of radio frequency coils is entirely surrounded by other coils of the plurality of radio frequency coils.

17. The radio frequency coils array as set forth in claim 14, wherein the plurality of radio frequency coils are arranged in an N×M array where N>2 and M>2.

18. The radio frequency coils array as set forth in claim 14, wherein at least some of the coils of the plurality of radio frequency coils share a common substrate.

19. A magnetic resonance imaging system comprising:
a main magnet producing a substantially temporally constant main magnetic field within a field of view;
magnetic field gradient coils that impose selected magnetic field gradients on the main magnetic field within the field of view;
a means for applying a radio frequency pulse to the field of view; and
at least one radio frequency coil as set forth in claim 1 arranged to detect a magnetic resonance signal induced by the applied radio frequency pulse.

20. A magnetic resonance imaging method comprising:
exciting magnetic resonance in an imaging subject; and
receiving a magnetic resonance signal using one or more radio frequency coils as set forth in claim 1 with the radio frequency antenna of each coil in proximity to the imaging subject.
